(19) United States
(12) Patent Application Publication
(10) Pub. No.: US 2025/0175125 A1
(43) Pub. Date: May 29, 2025

(54) AMPLIFYING CIRCUIT AND DOHERTY AMPLIFIER CIRCUIT

(71) Applicant: SUMITOMO ELECTRIC DEVICE INNOVATIONS, INC., Yokohama-shi (JP)

(72) Inventor: Takashi SUMIYOSHI, Yokohama-shi (JP)

(73) Assignee: SUMITOMO ELECTRIC DEVICE INNOVATIONS, INC., Yokohama-shi (JP)

(21) Appl. No.: 18/925,141

(22) Filed: Oct. 24, 2024

(30) Foreign Application Priority Data
Nov. 24, 2023 (JP) 2023-199244

(51) Int. Cl. H03F 1/02; H03F 3/24

(52) U.S. Cl. CPC H03F 1/0288; H03F 3/245

(57) ABSTRACT

An amplifying circuit includes a transistor that includes an input terminal receiving a high frequency signal and an output terminal outputting an amplified high frequency signal, an inductor connected in parallel to the transistor between the input terminal and the output terminal, and a capacitor connected in parallel to the transistor and connected in series to the inductor between the input terminal and the output terminal.

### CROSS REFERENCE TO RELATED APPLICATIONS

This application claims priority based on Japanese Patent Application No. 2023-199244 filed on Nov. 24, 2023, and the entire contents of the Japanese patent application are incorporated herein by reference.

### TECHNICAL FIELD

The present invention relates to an amplifying circuit and a Doherty amplifier circuit.

### BACKGROUND OF THE INVENTION

There has been known an N-way (N is three or more) Doherty amplifier circuit using a main amplifier and two or more peak amplifiers as an amplifying circuit (for example, Patent literature 1: U.S. Pat. No. 8,022,760 and Patent literature 2: U.S. patent Ser. No. 10/601,375).

### SUMMARY OF THE INVENTION

An amplifying circuit according to an embodiment of the present disclosure includes a transistor that includes an input terminal receiving a high frequency signal and an output terminal outputting an amplified high frequency signal, an inductor connected in parallel to the transistor between the input terminal and the output terminal, and a capacitor connected in parallel to the transistor and connected in series to the inductor between the input terminal and the output terminal.

### BRIEF DESCRIPTION OF THE DRAWINGS

FIG. 1 is a block diagram of an amplifying circuit according to a first embodiment.

FIG. 2 is a circuit diagram of a circuit A.

FIG. 3 is a circuit diagram of a circuit B.

FIG. 4 is a circuit diagram of a circuit C.

FIG. 5 is a diagram illustrating a maximum gain gmax with respect to a frequency in circuit C.

FIG. 6 is a diagram illustrating the maximum gain gmax with respect to the frequency in circuit C.

FIG. 7 is a circuit diagram of a circuit D.

FIG. 8 is a diagram illustrating the maximum gain gmax with respect to the frequency in circuit D.

FIG. 9 is a block diagram of a Doherty amplifier circuit according to a second embodiment.

FIG. 10 is a plan view of a semiconductor device in the second embodiment.

### DETAILED DESCRIPTION

A maximum gain of an amplifying circuit such as a Doherty amplifier circuit can be improved by suppressing a reverse transfer capacitance of a transistor.

The present disclosure aims to improve characteristics.

### Description of Embodiments of Present Disclosure

First, the contents of embodiments of the present disclosure will be listed and explained.

(1) An amplifying circuit according to an embodiment of the present disclosure includes a transistor that includes an input terminal receiving a high frequency signal and an output terminal outputting an amplified high frequency signal, an inductor connected in parallel to the transistor between the input terminal and the output terminal, and a capacitor connected in parallel to the transistor and connected in series to the inductor between the input terminal and the output terminal. As a result, the inductor compensates for a reverse transfer capacitance of the transistor. Thus, the gain of the amplifying circuit can be improved, and the characteristics can be improved.

(2) In (1), 1/((2π×f0)²×Cgd)+1/((2π×f0)²×C)≤L≤10/((2π×f0)²×Cgd)+10/((2π×f0)²×C) may be satisfied, where Cgd is a reverse transfer capacitance of the transistor, L is an inductance of the inductor, C is a capacitance of the capacitor, and f0 is a center frequency of an operation band. As a result, the inductor compensates for the reverse transfer capacitance. Thus, the characteristics can be improved.

(3) In (2), 1/(2π×f0×C)<2π×f0×L may be satisfied. Thus, the series circuit of the inductor and the capacitor can be inductive.

(4) In (3), C>Cgd may be satisfied. Thus, the capacitor can be used as a DC cut.

(5) In any one of (1) to (4), a maximum gain at a center frequency of an operation band between the input terminal and the output terminal may be larger than a maximum gain at the center frequency between the input terminal and the output terminal when the inductor and the capacitor are absent. Thus, the gain can be improved.

(6) In any one of (1) to (5), the transistor may be a field effect transistor (FET), the input terminal may be a gate of the FET, and the output terminal may be a drain of the FET. Thus, the characteristics of the FET can be improved.

(7) A Doherty amplifier circuit include a main amplifier comprising the amplifying circuit according to any one of (1) to (6) and a peak amplifier. Thus, the characteristics of the Doherty amplifier circuit can be improved.

(8) In (7), the peak amplifier may not include no inductor and no capacitor that are connected in parallel to the transistor between the input terminal and the output terminal of the transistor. Thus, the Doherty amplifier circuit can be miniaturized.

### DETAILS OF EMBODIMENTS OF PRESENT DISCLOSURE

Specific examples of an amplifying circuit and a Doherty amplifier circuit according to embodiments of the present disclosure will be described below with reference to the drawings. It is noted that, the present disclosure is not limited to these examples, but is defined by the scope of the claims, and is intended to include all modifications within the meaning and scope equivalent to the scope of the claims.

### First Embodiment

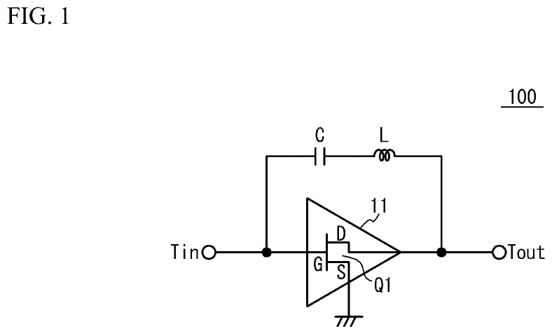

FIG. 1 is a block diagram of an amplifying circuit according to a first embodiment. The frequency of the high-frequency signal amplified by an amplifying circuit 100 is, for example, 0.5 GHz to 100 GHz. When amplifying circuit 100 is used as a high-output high-frequency amplifying circuit used in base stations of mobile communications, the frequency of the high-frequency signal is, for example, 0.5 GHz to 10 GHz.

As illustrated in FIG. 1, in amplifying circuit 100 of the first embodiment, an amplifier 11 is connected between an input terminal Tin and an output terminal Tout. Amplifier 11 includes a transistor Q1. Transistor Q1 is, for example, a field effect transistor (FET). A source S, a gate G, and a drain D of transistor Q1 are electrically connected to a reference potential such as ground, input terminal Tin, and output terminal Tout, respectively. Amplifier 11 amplifies a high-frequency signal input to input terminal Tin and outputs the amplified high-harmonic signal to output terminal Tout.

Transistor Q1 is, for example, a field effect transistor (FET), and is, for example, a gallium nitride high electron mobility transistor (GaN HEMT) or a laterally diffused metal oxide semiconductor (LDMOS).

A capacitor C and an inductor L connected in series are connected in parallel to amplifier 11 between input terminal Tin and output terminal Tout. Inductor L compensates for the reverse transfer capacitance (for example, a gate drain capacitance Cgd) of transistor Q1. Capacitor C is a capacitor for a DC cut.

### [Simulation]

To explain the operation of the first embodiment, simulations for several circuits A to D are described below.

### [Circuit A]

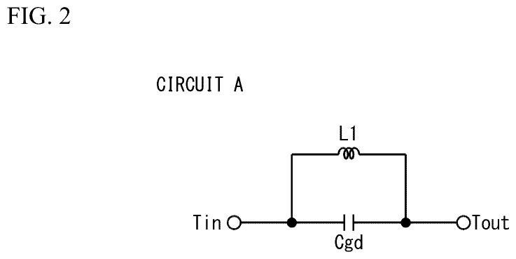

FIG. 2 is a circuit diagram of a circuit A. As illustrated in FIG. 2, an inductor L1 is connected in parallel to a gate-drain capacitance Cgd between input terminal Tin and output terminal Tout. At the resonant frequency of the parallel resonant circuit of gate-drain capacitance Cgd and inductor L1, the impedance between input terminal Tin and output terminal Tout increases. Thus, gate drain capacitance Cgd can be compensated. When a center frequency of an operation band is denoted by f0, an inductance of inductor L1 is denoted by L1, and a capacitance of gate drain capacitance Cgd is denoted by Cgd, an inductance L1 is represented by formula 1 when the parallel resonant circuit resonates at a center frequency f0.

$$L 1 = 1 / ( {( 2 π \times f 0 )}^{2} \times Cgd ) \qquad ( Formula 1 )$$

When f0 is 2.1 GHz and Cgd is 0.246 pF, L1 is calculated to be 23.1 nH.

### [Circuit B]

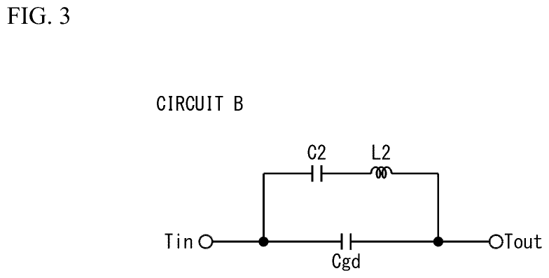

FIG. 3 is a circuit diagram of a circuit B. As illustrated in FIG. 3, a capacitor C2 is connected in parallel to gate-drain capacitance Cgd and in series to an inductor L2 between input terminal Tin and output terminal Tout. In circuit A, a direct current flows in parallel to gate-drain capacitance Cgd via inductor L1. Thus, capacitor C2 is provided for a DC cut. In circuit B, an inductance L2 of inductor L2 corresponding to capacitor C2 is set to be larger than inductance L1 of inductor L1. The relationship between L1, L2 and C2 is formula 2.

$$2 π \times f 0 \times L 1 = 2 π \times f 0 \times L 2 - 1 / ( 2 π \times f 0 \times C 2 ) \qquad ( Formula 2 )$$

From formula 2, inductance L2 of inductor L2 is expressed as formula 3.

$$L 2 = 1 / ( {( 2 π \times f 0 )}^{2} \times Cgd ) + 1 / ( {( 2 π \times f 0 )}^{2} \times C 2 ) \qquad ( Formula 3 )$$

When f0 is 2.1 GHz, Cgd is 0.246 pF and C2 is 0.5 pF, L2 is calculated to be 34.7 nH.

### [Circuit C]

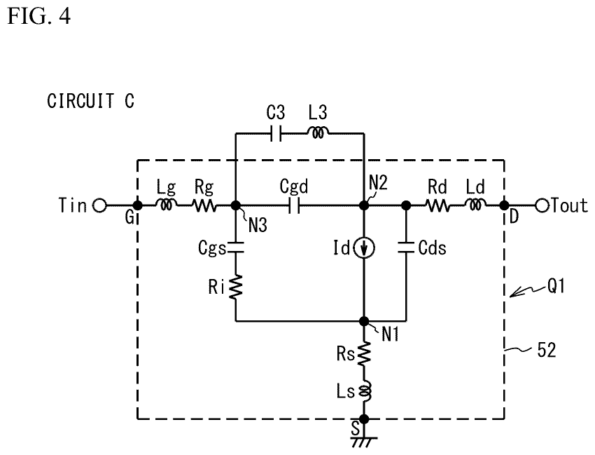

FIG. 4 is a circuit diagram of a circuit C. In circuit C, an inductor L3 and a capacitor C3 are connected in parallel to gate-drain capacitance Cgd in an equivalent circuit 52 of the transistor. Equivalent circuit 52 is an equivalent circuit of the FET.

In equivalent circuit 52, a drain-source current is represented by a current source Id. Current source Id and a drain-source capacitance Cds are connected in parallel between nodes N1 and N2. Node N1 is connected to source S via a source resistor Rs and a source inductor Ls. Node N2 is connected to drain D via a drain resistor Rd and a drain inductor Ld. A node N3 is connected to gate G via a gate resistor Rg and a gate inductor Lg. Gate-drain capacitance Cgd is connected between nodes N2 and N3. A gate-source capacitor Cgs and a channel resistor Ri are connected in series between nodes N3 and N1.

In circuit C, inductor L3 and capacitor C3 are connected in parallel to gate-drain capacitance Cgd between nodes N2 and N3.

The simulation was performed using the values of inductor L2 and capacitor C2 in circuit B as inductor L3 and capacitor C3. Equivalent circuit 52 is used as a GaN HEMT equivalent circuit. Cds is 0.246.

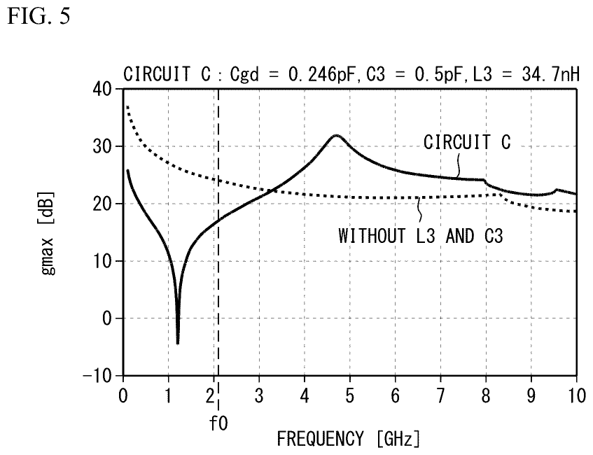

FIG. 5 is a diagram illustrating a maximum gain gmax with respect to a frequency in circuit C. Circuit C in FIG. 5 is the simulation result of circuit C, and “without L3 and C3” in FIG. 5 refers to the simulation result of the circuit without inductor L3 and capacitor C3. As illustrated in FIG. 5, in circuit C, the maximum gain is maximized in the vicinity of 4.7 GHz, but the maximum gain at center frequency f0 which is 2.1 GHz is lower than the maximum gain of the circuit without L3 and C3.

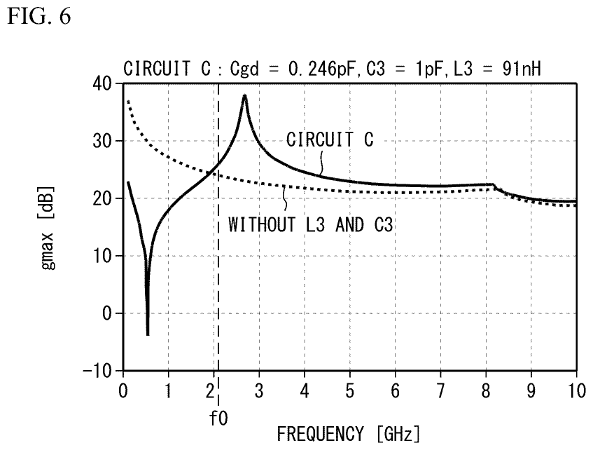

Thus, the values of inductor L3 and capacitor C3 were optimized. FIG. 6 is a diagram illustrating the maximum gain gmax with respect to the frequency in circuit C. The inductance of inductor L3 is 91 nH, and the capacitance of capacitor C3 is 1 pF. As illustrated in FIG. 6, the frequency at which the maximum gain is maximized in circuit C in FIG. 6 is lower than that in FIG. 5, and is about 2.7 GHz. Accordingly, the maximum gain at center frequency f0 which is 2.1 GHz is about 2 dB higher than the maximum gain at center frequency f0 of the circuit without L3 and C3.

### [Circuit D]

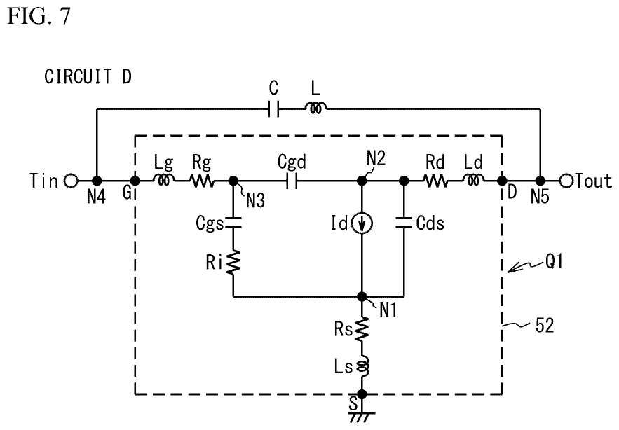

In an actual amplifying circuit, inductor L and capacitor C are connected in parallel to transistor Q1 between gate G and drain D. FIG. 7 is a circuit diagram of a circuit D. In circuit D, inductor L and capacitor C are connected in parallel to equivalent circuit 52 between a node N4 between gate G and input terminal Tin and a node N5 between drain D and output terminal Tout.

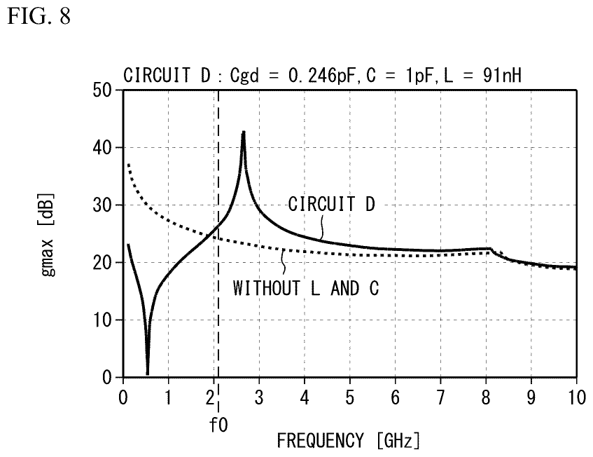

FIG. 8 is a diagram illustrating the maximum gain gmax with respect to the frequency in circuit D. “Without L and C” in FIG. 8 refers to the simulation result of the circuit without inductor L and capacitor C. The inductance of inductor L is 91 nH, and the capacitance of capacitor C is 1 pF. As illustrated in FIG. 8, the frequency at which the maximum gain is maximized in circuit D is about 2.7 GHz, which is substantially the same as that of circuit C in FIG. 6. The maximum gain at center frequency f0 which is 2.1 GHz is about 2 dB higher than the maximum gain at center frequency f0 of the circuit without L and C.

When f0 is 2.1 GHz, Cgd is 0.246 pF, and C2 is 1 pF, L2 is calculated from formula 3 to be 28.8 nH. In circuits C and D, it is considered that L and L3 are made larger than L2 calculated from formula 3 due to the influence of other elements of equivalent circuit 52.

As illustrated in FIG. 1 and FIG. 7, inductor L is connected in parallel to transistor Q1 between gate G (input terminal) and drain D (output terminal) of transistor Q1. Capacitor C is connected in parallel to transistor Q1 between gate G and drain D, and is connected in series to inductor L. Thus, inductor L compensates for the reverse transfer capacitance (gate drain capacitance Cgd) of transistor Q1. Thus, the gain of amplifying circuit 100 having transistor Q1 can be improved, and the characteristics can be improved.

An inductance L of inductor L is a value calculated by formula 3 when the influence of elements other than gate-drain capacitance Cgd of equivalent circuit 52 is small. When the influence of the elements other than gate-drain capacitance Cgd of equivalent circuit 52 is large, the inductance L of inductor L is larger than a value calculated by formula 3. Thus, 1/((2π×f0)²×Cgd)+1/((2π×f0)²×C)≤L is satisfied. Thus, inductor L compensates for gate drain capacitance Cgd. Thus, the characteristics can be improved.

When the influence of the elements other than gate-drain capacitance Cgd of equivalent circuit 52 is large, 1/((2π×f0)²×Cgd)+1/((2π×f0)²×C) may be satisfied, or 2/((2π×f0)²×Cgd)+2/((2π×f0)²×C)≤L may be satisfied.

When inductance L is large, the resonance frequency with gate-drain capacitance Cgd is lower than center frequency f0. Thus, the gain decreases. In this respect, L≤10/((2π×f0)²×Cgd)+10/((2π×f0)²×C) may be satisfied, L≤8/((2π×f0)²×Cgd)+8/((2π×f0)²×C) may be satisfied, or L≤6/((2π×f0)²×Cgd)+6/((2π×f0)²×C) may be satisfied.

In order to make the series circuit of capacitor C and inductor L inductive, 1/(2π×f0×C)<2π×f0×L is satisfied. 1/(2π×f0×C)≤π×f0×L/2 is satisfied, or 1/(2π×f0×C)≤π×f0×L/4 is satisfied. 1/(2π×f0×C)≥2π×f0×L/20 is also satisfied.

In order to use capacitor C as a DC cut, capacitance C is relatively large. For example, C>Cgd can be satisfied. C≥1.5×Cgd may be satisfied, C≥2×Cgd may be satisfied, or C≤10×Cgd may be satisfied.

As illustrated in FIG. 8, the maximum gain gmax at center frequency f0 between gate G and drain D in circuit D is larger than a maximum gain gmax0 at center frequency f0 when inductor L and capacitor C are not provided. Thus, the gain can be improved.

The maximum gain gmax can be set to be 0.5 dB more than gmax0, or it can be set to be 1 dB or more.

Transistor Q1 does not have to be an FET. Inductor L and capacitor C may be connected in parallel to the reverse transfer capacitance of transistor Q1. When transistor Q1 is an FET and is a source-ground amplifying circuit, the equivalent circuit of transistor Q1 is equivalent circuit 52 of FIG. 7. In this case, the gain can be improved by providing inductor L and capacitor C.

### Second Embodiment

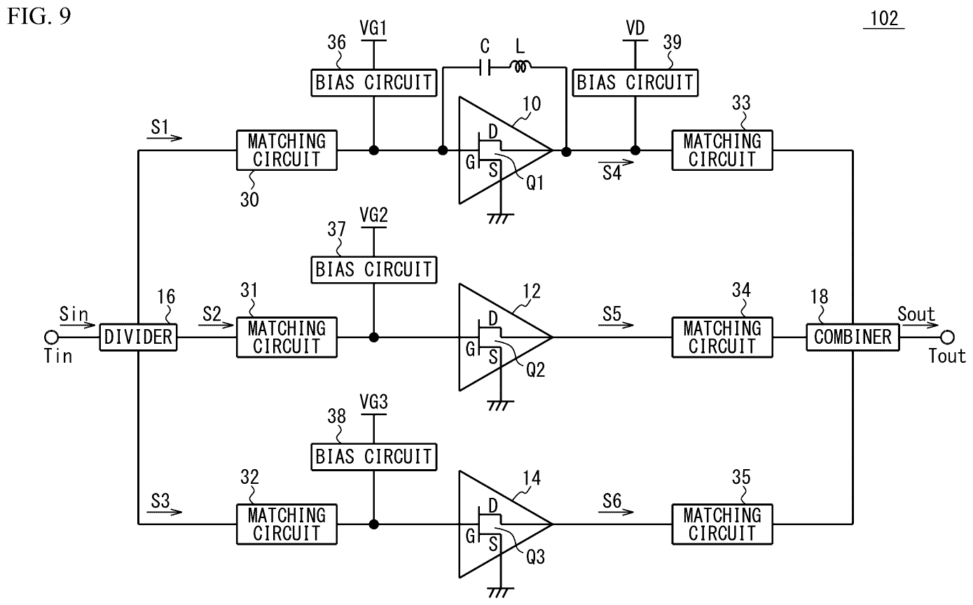

A second embodiment is an example in which the amplifying circuit of the first embodiment is used as a Doherty amplifier circuit. FIG. 9 is a block diagram of a Doherty amplifier circuit according to the second embodiment.

As illustrated in FIG. 9, in a Doherty amplifier circuit 102, a main amplifier 10 and peak amplifiers 12 and 14 are connected in parallel between a divider 16 and a combiner 18. Thus, Doherty amplifier circuit 102 is a three-way amplifying circuit. The Doherty amplifier circuit 102 may be an N-way Doherty amplifier circuit having one peak amplifier or three or more peak amplifiers.

A high frequency signal is input to input terminal Tin as an input signal Sin. Divider 16 divides input signal Sin input to input terminal Tin into signals S1, S2, and S3. Divider 16 is, for example, a Wilkinson-type divider.

A path through which signal S1 is input includes a matching circuit 30, a bias circuit 36, main amplifier 10, a bias circuit 39, and a matching circuit 33. A path through which signal S2 is input includes a matching circuit 31, a bias circuit 37, peak amplifier 12, and a matching circuit 34. A path through which signal S3 is input includes a matching circuit 32, a bias circuit 38, peak amplifier 14, and a matching circuit 35.

Matching circuits 30 to 32 match impedances seen from divider 16 toward matching circuits 30 to 32 to the respective impedances seen from matching circuits 30 to 32 toward main amplifier 10, peak amplifiers 12 and 14. Bias circuits 36 to 38 supply gate bias voltages VG1 to VG3 to gates G of main amplifier 10, peak amplifiers 12 and 14, respectively, to suppress the leakage of signals S1 to S3 to the bias terminals.

Main amplifier 10 and peak amplifiers 12 and 14 amplify signals S1, S2, and S3 and output amplified signals S4, S5, and S6, respectively. Bias circuit 39 supplies a drain bias voltage VD to drain D of main amplifier 10, and suppresses the leakage of signal S4 to the bias terminal. Matching circuits 33 to 35 match impedances seen from matching circuits 33 to 35 toward main amplifier 10 and peak amplifiers 12 and 14 to the respective impedances seen from matching circuits 33 to 35 toward combiner 18. Combiner 18 combines signals S4 and S6, and outputs the combined signal to output terminal Tout as an output signal Sout.

Main amplifier 10 performs class-A or class-AB operation, and peak amplifiers 12 and 14 perform class-C operation. When the input power of input signal Sin is small, main amplifier 10 operates, and peak amplifiers 12 and 14 do not operate. When the input power increases, main amplifier 10 and peak amplifier 12 operate, and peak amplifier 14 does not operate. When the input power further increases, all of main amplifier 10 and peak amplifiers 12 and 14 operate.

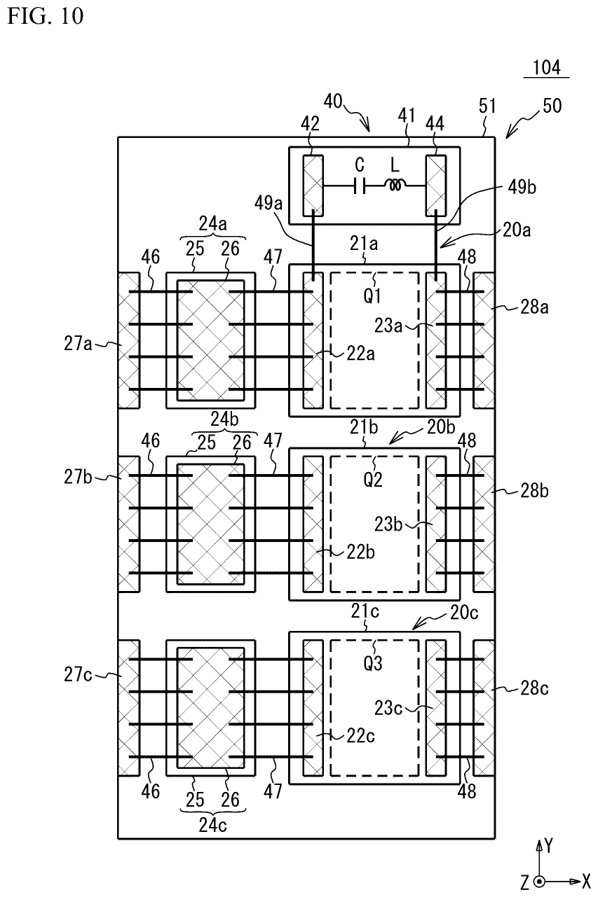

FIG. 10 is a plan view of a semiconductor device in the second embodiment. In FIG. 10, the lid of a package 50 is not illustrated. The thickness direction of a base 51 of package 50 is defined as a Z direction, the direction from leads 27a to 27c to leads 28a to 28c is defined as an X direction, and the direction orthogonal to the X direction and the Z direction is defined as a Y direction.

As illustrated in FIG. 10, in a semiconductor device 104, package 50 has base 51 having at least a conductive upper surface. Base 51 is a conductive substrate such as a copper-molybdenum laminated substrate. A reference potential such as a ground potential is supplied to base 51. Semiconductor chips 20a to 20c, capacitive components 24a to 24c, and a passive chip 40 are mounted on base 51.

Leads 27a to 27c are provided on a negative side of the base 51 in the X direction with an insulating layer (not illustrated) interposed between the base 51 and leads 27a to 27c. Leads 28a to 28c are provided on a positive side of the base 51 in the X direction with an insulating layer (not illustrated) interposed between the base 51 and leads 28a to 28c. Leads 27a to 27c and 28a to 28c are metal layers or metal plates made of, for example, copper. Signals S1 to S3 are input to leads 27a to 27c, respectively, and signals S4 to S6 are output from leads 28a to 28c, respectively.

Semiconductor chip 20a includes a substrate 21a, transistor Q1, pads 22a and 23a provided on the upper surface of substrate 21a, and an electrode (not illustrated) provided on the lower surface of substrate 21a. Pads 22a and 23a and the electrode on the lower surface are electrically connected to gate G, drain D, and source S of transistor Q1, respectively. A semiconductor chip 20b includes a substrate 21b, a transistor Q2, pads 22b and 23b provided on the upper surface of substrate 21b, and an electrode provided on the lower surface of substrate 21b. Pads 22b and 23b and the electrode on the lower surface are electrically connected to gate G, drain D, and source S of transistor Q2, respectively. Semiconductor chip 20c includes a substrate 21c, a transistor Q3, pads 22c and 23c provided on the upper surface of substrate 21c, and an electrode provided on the lower surface of substrate 21c. Pads 22c and 23c and the electrode on the lower surface are electrically connected to gate G, drain D, and source S of transistor Q3, respectively.

Substrates 21a to 21c are semiconductor substrates. When transistors Q1 to Q3 are GaN HEMTs, substrates 21a to 21c are, for example, silicon carbide (SiC) substrates, sapphire substrates, or gallium nitride (GaN) substrates. When transistors Q1 to Q3 are LDMOS, substrates 21a to 21c are, for example, silicon (Si) substrates. Pads 22a to 22c, 23a to 23c and the electrode on the lower surface are metal layers such as gold layers.

Each of capacitive components 24a to 24c includes a dielectric substrate 25, an electrode 26 provided on the upper surface of dielectric substrate 25, and an electrode provided on the lower surface of dielectric substrate 25. Electrode 26 and the electrode on the lower surface interposing dielectric substrate 25 form a capacitor. Dielectric substrate 25 is, for example, an alumina substrate or a barium titanate substrate. Electrode 26 is, for example, a metal layer such as a gold layer.

Bonding wires 46 electrically connect leads 27a to 27c to electrodes 26 of capacitive components 24a to 24c, respectively. Bonding wires 47 electrically connect electrodes 26 of capacitive components 24a to 24c to pads 22a to 22c, respectively. Bonding wires 48 electrically connect pads 23a to 23c and leads 28a to 28c, respectively. Bonding wires 46 to 48 are, for example, metal wires such as gold wires or aluminum wires.

Bonding wires 46 and 47 function as inductors, and capacitive components 24a to 24c function as capacitors. Bonding wires 46, 47 and capacitive components 24a to 24c correspond to matching circuits 30 to 32 of the T-type LCL circuit.

Passive chip 40 is provided in semiconductor chip 20a in the positive direction of the Y direction. Passive chip 40 includes a substrate 41 and pads 42 and 44 provided on the upper surface of substrate 41. Capacitor C and inductor L are connected in series between pads 42 and 44. A bonding wire 49a electrically connects pad 22a and pad 42. A bonding wire 49b electrically connects pad 23a and pad 44. Thus, inductor L and capacitor C can be connected in parallel to transistor Q1.

As in the second embodiment, inductor L and capacitor C may be connected in parallel to at least one amplifier of main amplifier 10 and peak amplifiers 12 and 14 of Doherty amplifier circuit 102. In particular, main amplifier 10 mainly amplifies input signal Sin. Thus, inductor L and capacitor C are connected in parallel to main amplifier 10. Thus, the characteristics such as the gain of Doherty amplifier circuit 102 can be improved.

Peak amplifiers 12 and 14 do not include an inductor and a capacitor connected in parallel to transistors Q2 and Q3 between gate G and drain D of transistors Q2 and Q3. Peak amplifiers 12 and 14 operate only when the input power is large. Thus, inductor L and capacitor C may not be provided in peak amplifiers 12 and 14. Thus, the Doherty amplifier circuit can be miniaturized.

Although a three-way Doherty amplifier circuit has been described as an example, a two-way Doherty amplifier circuit without peak amplifier 14 may be used. Further, an N-way Doherty amplifier circuit in which N is four or more may be used. In this case, N−1 peak amplifiers may be provided.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

1. An amplifying circuit comprising:
a transistor that includes an input terminal receiving a high frequency signal and an output terminal outputting an amplified high frequency signal;
an inductor connected in parallel to the transistor between the input terminal and the output terminal; and
a capacitor connected in parallel to the transistor and connected in series to the inductor between the input terminal and the output terminal.

2. The amplifying circuit according to claim 1, wherein
1/((2π×f0)²×Cgd)+1/((2π×f0)²×C)≤L≤10/((2π×f0)²×Cgd)+10/((2π×f0)²×C) is satisfied,
where Cgd is a reverse transfer capacitance of the transistor, L is an inductance of the inductor, C is a capacitance of the capacitor, and f0 is a center frequency of an operation band.

3. The amplifying circuit according to claim 2, wherein
1/(2π×f0×C)<2π×f0×L is satisfied.

4. The amplifying circuit according to claim 3, wherein
C>Cgd is satisfied.

5. The amplifying circuit according to claim 1, wherein
a maximum gain at a center frequency of an operation band between the input terminal and the output terminal is larger than a maximum gain at the center frequency between the input terminal and the output terminal when the inductor and the capacitor are absent.

6. The amplifying circuit according to claim 1, wherein
the transistor is a field effect transistor (FET), and
the input terminal is a gate of the FET, and the output terminal is a drain of the FET.

7. A Doherty amplifier circuit comprising:
a main amplifier including the amplifying circuit according to claim 1; and
a peak amplifier.

8. The Doherty amplifier circuit according to claim 7, wherein
the peak amplifier includes no inductor and no capacitor that are connected in parallel to the transistor between the input terminal and the output terminal of the transistor.
